(19) United States
(12) Patent Application Publication
(10) Pub. No.: US 2019/0096965 A1
(43) Pub. Date: Mar. 28, 2019

(54) Flexible Solar Graphics Display

(71) Applicant: Brandon Mairs, Lathrop, CA (US)

(72) Inventor: Brandon Mairs, Lathrop, CA (US)

(73) Assignee: Arubixs Inc., Berkeley, CA (US)

(21) Appl. No.: 15/484,127

(22) Filed: Apr. 10, 2017

(51) Int. Cl. H01L 27/32; H01L 27/30; H01L 27/28; H02S 40/38; H02J 50/30; H01L 31/12; H04M 1/02

(52) U.S. Cl. CPC H01L 27/3227; H01L 27/301; H01L 27/288; H04M 1/0266; H02J 50/30; H01L 31/125; H04M 1/0214; H02S 40/38

(57) ABSTRACT

A durable, reliable, ecofriendly, and convenient way for supplementing the charging of a cellular smart device battery using a flexible display apparatus comprising a transparent flexible touch sensor, transparent flexible graphics display, flexible solar cell, flexible heat shielding film and flexible battery.

### CROSS REFERENCE TO RELATED APPLICATIONS

This application claims the benefit of U.S. Provisional Patent Application No. 62/320,620 filed Apr. 11, 2016, entitled “Flexible Solar Graphics Display”, the disclosure of which is incorporated by reference herein in its entirety.

### BACKGROUND OF THE INVENTION

The Present invention is related to charging of a cellular smart device using a flexible transparent display and flexible solar cell, such as a polycrystalline silicon solar cell.

Currently there are no cellular smart devices that have built in solar charging capabilities. Current solar charging capabilities for “cellular smart devices” involve attaching an aftermarket external solar charging apparatus to the rear of the cellular smart device or connecting the device into it via a cable to an external solar charging device that can be placed freely around the cellular smart device. This is an inconvenient method for the end user to charge their cellular smart device because the device has to be facing upside down and oriented away from overhead light sources, making the device inoperable while charging or tethered to a solar charging decreasing its mobility.

One attempt at solar charging involves solar charging a cellular smart device but does not contain any method to retain the charge, thereby greatly reducing the functionality of the device (Osinga, 2011, EP 2 605 281 A1). Finally, no solar charging device provides for a flexibility of the device.

### SUMMARY OF THE INVENTION

It is therefore an object of the present invention to provide a durable, reliable, eco-friendly, and convenient way for supplementing the charging of a cellular smart device battery using a flexible display apparatus.

### BRIEF DESCRIPTION OF DRAWINGS

FIG. 1 is an example of the layer cut away of display apparatus which includes touch sensor, display substraights, and solar cell.

FIG. 2 is an example of the side view of the display apparatus which shows the horizontal flexibility of the display apparatus layers including the touch sensor, display substraights, and solar cell.

FIG. 3 is an example of the top view looking down through the display apparatus into the top surface of the solar cell.

FIG. 4 is an example of a side view sun rays (or other light source) shining through the layers of display assembly to the solar cell.

### DETAILED DESCRIPTION OF PREFERRED EMBODIMENTS OF THE INVENTION

Referring to FIG. 1, the top layer (1) is the transparent flexible touch sensor. Underneath the touch sensor are the multiple layers of flexible transparent graphics display, such as an organic light emitting display (“OLED”) (the graphics display and substrates) (2), which enable the display show images. The touch sensor (1) and transparent display (2) may be bonded with a flexible transparent adhesive (not shown). Underneath the transparent display substraights (2) is a flexible solar cell (3), such as a polycrystalline solar cell, which may also be bonded to the substrates (2) with a flexible transparent adhesive (not shown). This solar cell (3) acts as a secondary charging method for a mobile cellular device flexible battery when the entire display apparatus is installed. A flex circuit (5) is bonded to the touch sensor as well as the transparent display and is also connected to a flexible host processor (not shown). A flexible power supply ribbon cable (6) is bonded to the solar cell (3) and connected to the device flexible battery (not shown).

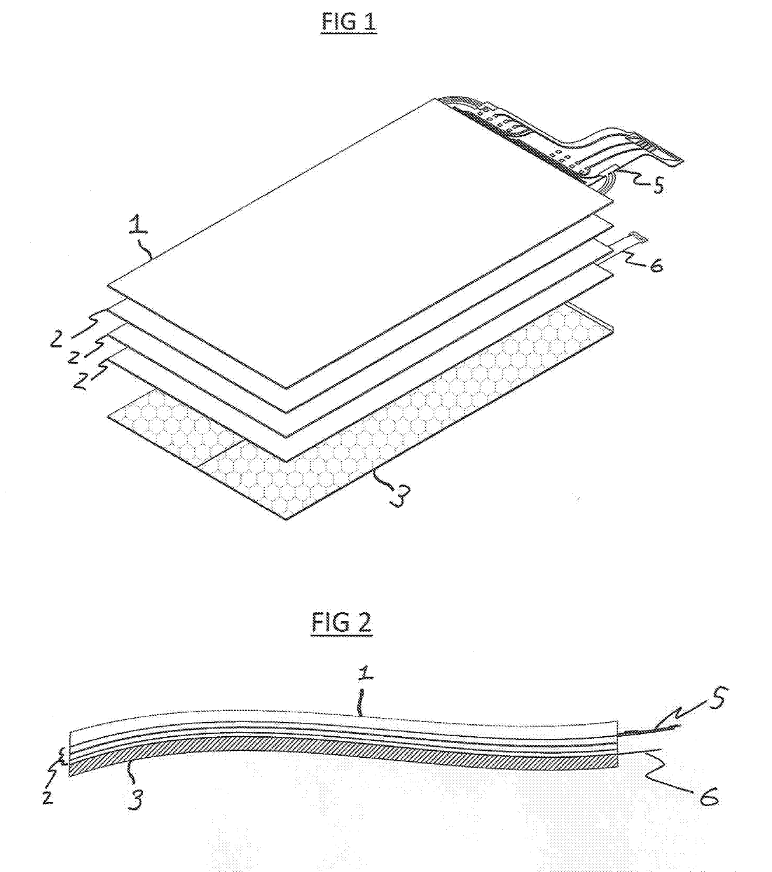

Referring now to FIG. 2, the flexibility of the flexible solar graphics display apparatus is shown. The flexible transparent touch sensor (1) is the top layer, under the touch sensor is the transparent flexible display and several layers of substrates (2) of the flexible display. The flexible display may comprise an OLED display. Underneath the flexible display is the flexible solar cell. (3) All of these paired together show the flexibility and bendability of the display charged by the device flexible battery component (not shown) which is supplementary charged by the solar cell (3). The solar cell may comprise a solar cell array of a plurality of solar cells to further increase flexibility of the cellular device. Said solar cell array may comprise an array of polycrystalline solar cells.

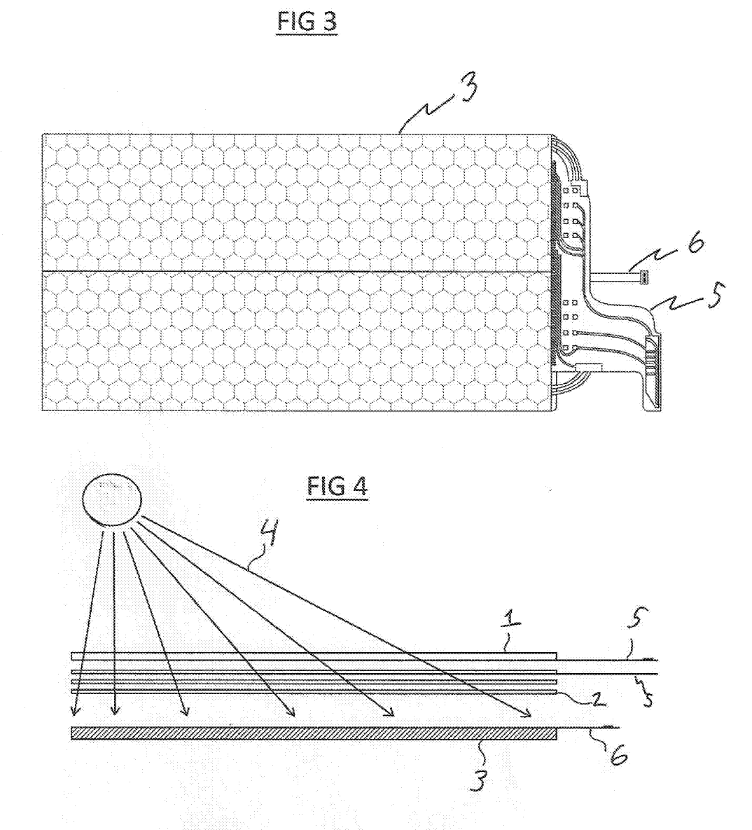

Referring to FIG. 3. The flexible solar cell (3) is visible looking down through the flexible transparent touch sensor (1) and the transparent flexible graphics display (2). This allows the solar cell to collect light rays which are converted to an energy source for a cellar mobile device flexible battery.

Referring now to FIG. 4, sun light (or other light from another light source) (4) passes through the transparent flexible touch sensor (1), and the transparent flexible graphics display substrates. (2) Once the light (4) pass through the touch sensor (1) and display substraights (2) they contact the flexible solar cell. (3) The light (4) is then converted into energy and sent through the positive and negative flexible power supply ribbon cable (6) which is connected to the flexible battery component (not shown) of the cellular device. This process allows as a secondary charging method for the host cellar mobile device battery.

In one embodiment of the invention, the solar charging display and battery apparatus for mobile devices, comprises a flexible transparent screen with a front side and a back side; a flexible touch sensor with a front side and a back side, said flexible touch sensor front side connected to said flexible transparent screen back side; a flexible display with a front side and a back side, said transparent touch sensor back side connected to said display front side; at least one flexible solar cell with a front side and a back side and a connecting means for an efflux of electrons, said solar cell front side connected to said screen back side; a flexible heatsheilding film with a front side and a back side, said flexible solar cell back sided connected to said heatsheilding film front side;

A circuit board with a front side and a back side, said circuit board front side connected to said flexible heatsheilding film back side; a flexible second heatsheilding film with a front side and a back side, said flexible circuit board back sided connected to said second heatsheilding film front side; at least one battery with a front side and a back side and connecting means for in influx and efflux of electrons, said battery front side connected to said circuit board back side and said connecting means for an influx of electrons connected to said solar cell connecting means for an efflux of electrons; and, at least one wireless charging coil designed for wireless charging of said batteries, connected to said battery connecting means for influx of electrons.

In another embodiment of the invention, said solar cell comprises an array of solar cells.

In still another embodiment of the invention, said battery further comprises a battery array with each battery of said battery array having wireless charging coils.

In yet another embodiment of the invention, said solar cell comprises a solar cell array.

In another embodiment of the invention, said solar cell comprises a solar cell array and said battery comprises a battery array with each battery of said battery array having wireless charging coils.

In yet another embodiment of the invention, each said solar cell of said solar cell array is congruent to a corresponding battery of said battery array.

1. A solar charging battery apparatus for mobile devices, comprising:
A flexible transparent screen with a front side and a backside;
A flexible touch sensor with a front side and a backside, said flexible touch sensor front side connected to said flexible transparent screen backside;
A flexible display with a front side and a backside, said transparent touch sensor back side connected to said display front side;
At least one flexible solar cell with a front side and a backside and a connecting means for an efflux of electrons, said solar cell front side connected to said screen backside;
A flexible heatsheilding film with a front side and a backside, said flexible solar cell back sided connected to said heatsheilding film front side;
A circuit board with a front side and a back side, said circuit board front side connected to said flexible heatsheilding film back side;
A flexible second heatsheilding film with a front side and a backside, said flexible circuit board back sided connected to said second heatsheilding film front side;
At least one battery with a front side and a back side and connecting means for in influx and efflux of electrons, said battery front side connected to said circuit board back side and said connecting means for an influx of electrons connected to said solar cell connecting means for an efflux of electrons; and,
At least one wireless charging coil designed for wireless charging of said batteries, connected to said battery connecting means for influx of electrons.

2. The apparatus of claim 1, wherein said solar cell comprises an array of solar cells.

3. The apparatus of claim 1, wherein said battery further comprises a battery array with each battery of said battery array having wireless charging coils.

4. The apparatus of claim 1 wherein said solar cell comprises a solar cell array and said battery comprises a battery array with each battery of said battery array having wireless charging coils.

5. The apparatus of claim 4 wherein each said solar cell of said solar cell array is congruent to a corresponding battery of said battery array.
